(19) United States
(12) Patent Application Publication
(10) Pub. No.: US 2012/0056687 A1
(43) Pub. Date: Mar. 8, 2012

(54) VOLTAGE CONTROL OSCILLATOR

(75) Inventors: Ka-Un Chan, Zhubei City (TW); Yung-Ming Chiu, New Taipei City (TW)

(73) Assignee: REALTEK SEMICONDUCTOR CORP., Hsinchu (TW)

(21) Appl. No.: 13/222,177

(22) Filed: Aug. 31, 2011

(30) Foreign Application Priority Data
Sep. 6, 2010 (TW) 99130112

(51) Int. Cl. H03L 1/00

(52) U.S. Cl. 331/186

(57) ABSTRACT

A voltage control oscillator implemented in an integrated circuit includes a supply circuit and an oscillating circuit. The supply circuit, implemented with an input/output (I/O) interface element, receives an I/O reference voltage signal and provides a power signal accordingly. The oscillating circuit, implemented with a core circuit element, provides an oscillation signal in response to the power signal. A swing of the oscillation signal is determined according to a level of an I/O reference voltage signal.

This application claims the benefit of Taiwan application Serial No. 99130112, filed Sep. 6, 2010, the subject matter of which is incorporated herein by reference.

### BACKGROUND OF THE INVENTION

1. Field of the Invention

The invention relates in general to a voltage control oscillator (VCO) implemented with an integrated circuit, and more particularly to an integrated circuit operating in response to an input/output (I/O) reference voltage of the integrated circuit.

2. Description of the Related Art

In the existing art, a voltage control oscillator (VCO) has been widely utilized as a clock generator, which is applied to many occasions, such as a phase-locked loop (PLL), a delay locked loop (DLL), and the like. For example, the conventional VCO is often implemented with an integrated circuit, which includes an oscillating circuit operating in response to a core supply voltage (Core VDD). Generally speaking, the swing and the quality of the clock signal provided by the VCO relate to the level of the core voltage. However, with the continuous improvement of the semiconductor manufacturing process, the level of the core supply voltage is continuously lowered, so that the quality of the clock signal provided by the VCO declines. Thus, it is an important subject in the industry to provide a VCO capable of providing a clock signal with a good quality when the core supply voltage is lowered.

### SUMMARY OF THE INVENTION

The invention is directed to a voltage control oscillator, which is implemented with an integrated circuit and has a supply circuit, which is implemented with an input/output (I/O) interface element and operates in response to an I/O supply voltage (VDD) provided to the I/O interface of the integrated circuit. Thus, compared with the conventional VCO implemented with the integrated circuit, the VCO of the invention has the advantages of performing the oscillation operation and generating the clock signal with the better quality in response to the I/O supply voltage having the level higher than the core supply voltage (Core VDD).

According to the present invention, a voltage control oscillator implemented in an integrated circuit is provided. The voltage control oscillator includes a supply circuit and an oscillating circuit. The supply circuit, implemented with an input/output interface element, receives an I/O reference voltage signal and provides a power signal accordingly. The oscillating circuit, implemented with a core circuit element, provides an oscillation signal in response to the power signal. A swing of the oscillation signal is determined according to a level of the I/O reference voltage signal.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a block diagram showing a voltage control oscillator according to an embodiment of the invention.

FIG. 2 is a detailed block diagram showing a supply circuit 12 of FIG. 1.

FIG. 3 is another detailed block diagram showing the supply circuit 12 of FIG. 1.

FIG. 4 is still another detailed block diagram showing the supply circuit 12 of FIG. 1.

FIG. 5 is a detailed block diagram showing an oscillating circuit 14 of FIG. 1.

### DETAILED DESCRIPTION OF THE INVENTION

The voltage control oscillator according to the embodiment of the invention performs an oscillation operation in response to an input/output supply voltage (VDD) provided to an integrated circuit.

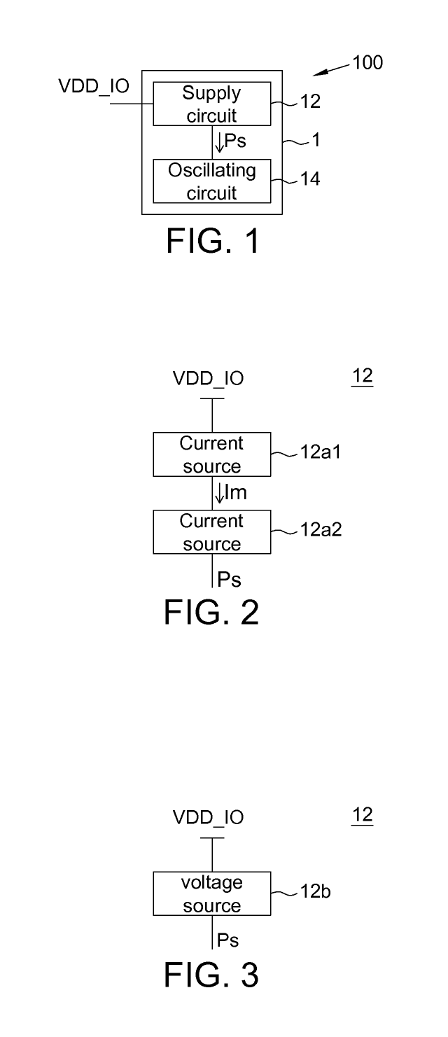

FIG. 1 is a block diagram showing a voltage control oscillator (VCO) 1 according to an embodiment of the invention. As shown in FIG. 1, the VCO 1 of this embodiment is implemented in an integrated circuit 100. The VCO 1 includes a supply circuit 12 and an oscillating circuit 14. The supply circuit 12, implemented with an input/output (I/O) interface element, receives an I/O reference voltage signal VDD_IO and provides a power signal Ps accordingly. For example, the level of the I/O reference voltage signal VDD_IO is higher than the voltage withstanding ability of the typical core device in the integrated circuit 100. Accordingly, compared with the core device in the integrated circuit 100, the I/O interface element has the higher voltage withstanding ability and thus can operate in the environment where the I/O reference voltage signal VDD_IO serves as the operation voltage.

FIG. 2 is a detailed block diagram showing the supply circuit 12 of FIG. 1. In one example, the supply circuit 12 is implemented with two current sources 12a1 and 12a2. For example, the current source 12a1, directly driven by the I/O reference voltage signal VDD_IO, is implemented with the I/O interface element with the higher voltage withstanding ability, for example, to generate an intermediate current signal Im according to the I/O reference voltage signal VDD_IO. The current source 12a2 can be selectively implemented with the I/O interface element having the higher voltage withstanding ability or the typical core device, and provide the power signal Ps in the form of a constant current in response to the intermediate current signal Im.

FIG. 3 is another detailed block diagram showing the supply circuit 12 of FIG. 1. In another example, the supply circuit 12 may also be implemented with a voltage source 12b. The voltage source 12b is implemented with the I/O interface element with the higher voltage withstanding ability, and provides the power signal Ps in the form of a constant voltage in response to the I/O reference voltage signal VDD_IO.

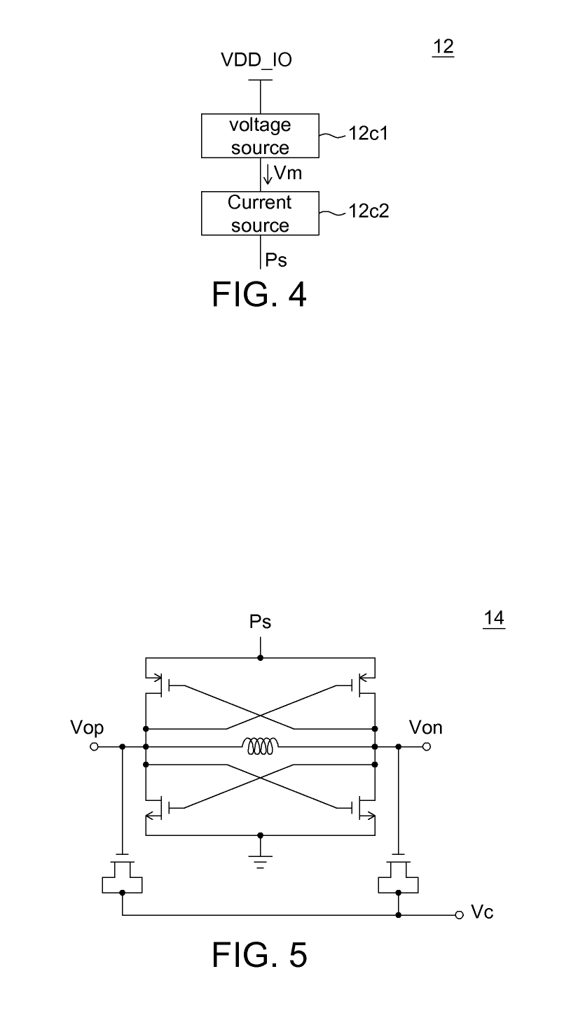

FIG. 4 is still another detailed block diagram showing the supply circuit 12 of FIG. 1. In still another example, the supply circuit 12 may also be implemented with a voltage source 12c1 and a current source 12c2. For example, the voltage source 12c1 directly driven by the I/O reference voltage signal VDD_IO is implemented with the I/O interface element having the higher voltage withstanding ability, and generates an intermediate voltage signal Vm according to the I/O reference voltage signal VDD_IO. For example, the swing of the intermediate voltage signal Vm is lower than the withstanding voltage of the core device in the integrated circuit 100. Thus, the current source 12c2 can be selectively implemented with the I/O interface element having the high voltage withstanding ability or the typical core device, and provide the power signal Ps in the form of the constant current in response to the I/O reference voltage signal VDD_IO.

The oscillating circuit 14 is implemented with the core circuit element having the lower voltage withstanding ability. The oscillating circuit 14 provides an oscillation signal CLK in response to the power signal Ps. The swing of the oscillation signal CLK is determined according to the level of the I/O reference voltage signal VDD_IO. With the increase of the level of the I/O reference voltage signal VDD_IO, the voltage level of the power signal Ps provided to the oscillating circuit 14 is also correspondingly increased. Thus, the oscillating circuit 14 can generate the oscillation signal CLK with the larger swing in response to the higher voltage level. Generally speaking, the oscillation signal CLK with the larger swing has the better clock signal quality.

For example, the oscillating circuit 14 is a complementary inductor capacitor resonance tank (LC Tank) voltage control oscillator, as shown in FIG. 5. In other examples, the oscillating circuit 14 may also be implemented with other types of oscillators.

The VCO according to the embodiment of the invention is implemented with the integrated circuit and has the supply circuit, implemented with the I/O interface element, for operating in response to the I/O supply voltage (VDD) provided to the I/O interface of the integrated circuit. Thus, compared with the conventional VCO implemented with the integrated circuit, the VCO of the invention has the advantages of performing the oscillation operation and generating the clock signal with the better quality in response to the I/O supply voltage having the level higher than the core supply voltage (Core VDD).

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A voltage control oscillator implemented in an integrated circuit, the voltage control oscillator comprising:
a supply circuit, implemented with an input/output (I/O) interface element, receiving an I/O reference voltage signal and providing a power signal accordingly; and
an oscillating circuit, implemented with a core circuit element, providing an oscillation signal in response to the power signal, wherein a swing of the oscillation signal is determined according to a level of the I/O reference voltage signal.

2. The voltage control oscillator according to claim 1, wherein the supply circuit comprises:
a first current source circuit, providing an intermediate power signal in response to the I/O reference voltage signal; and
a second current source circuit, providing the power signal, which is a current signal, in response to the intermediate power signal.

3. The voltage control oscillator according to claim 1, wherein the supply circuit comprises:
a regulator circuit, providing an intermediate power signal in response to the I/O reference voltage signal; and
a current source circuit, providing the power signal, which is a current signal, in response to the intermediate power signal.

4. The voltage control oscillator according to claim 1, wherein the supply circuit comprises:
a regulator circuit, providing the power signal in response to the I/O reference voltage signal, wherein the power signal is a voltage signal.
